(19) United States
(12) Patent Application Publication
(10) Pub. No.: US 2012/0228109 A1
(43) Pub. Date: Sep. 13, 2012

(54) SENSOR, KEYBOARD AND METHOD FOR MANUFACTURING SENSOR

(75) Inventors: Dongdong WANG, Torrance, CA (US); Christopher Lee KELLER, Torrance, CA (US); Masataka ITO, Torrance, CA (US); Yoshitsugu WAKAZONO, Torrance, CA (US)

(73) Assignee: IBIDEN Co., Ltd., Ogaki-shi (JP)

(21) Appl. No.: 13/408,294

(22) Filed: Feb. 29, 2012

Related U.S. Application Data
(60) Provisional application No. 61/450,181, filed on Mar. 8, 2011.

(51) Int. Cl. H03K 17/975; H01G 4/00; H01G 5/16; H05K 3/36

(52) U.S. Cl. 200/600; 29/830; 361/301.1; 361/290

(57) ABSTRACT

A sensor includes a first printed wiring board having a first electrode made of a metal film, a second printed wiring board facing the first printed wiring board and having a second electrode made of a metal film, the second electrode being positioned on the second printed wiring board such that the second electrode faces the first electrode of the first printed wiring board, and a dielectric body spacing the first electrode and the second electrode apart such that the first electrode, the second electrode and the dielectric body form a capacitor.

### CROSS-REFERENCE TO RELATED APPLICATIONS

The present application is based on and claims the benefits of priority to U.S. Application No. 61/450,181, filed Mar. 8, 2011, the entire contents of which are incorporated herein by reference.

### BACKGROUND OF THE INVENTION

1. Field of the Invention

The present invention relates to a sensor, a keyboard and a method for manufacturing a sensor.

2. Discussion of the Background

Usually, sensors for acceleration, temperature, pressure, angle and the like used in mobile devices are manufactured using a semiconductor manufacturing process or MEMS technology (MEMS: Micro Electro Mechanical Systems). As for accelerometers manufactured using MEMS technology, a sensor is described in Analog Devices, Inc., Low Cost±2 g/10 g Dual Axis, iMEMS (R) Accelerometers with Digital Output, the United States, 1999. The contents of this publication are incorporated herein by reference in their entirety.

### SUMMARY OF THE INVENTION

According to one aspect of the present invention, a sensor includes a first printed wiring board having a first electrode including a metal film, a second printed wiring board facing the first printed wiring board and having a second electrode including a metal film, the second electrode being positioned on the second printed wiring board such that the second electrode faces the first electrode, and a dielectric body spacing the first electrode and the second electrode apart such that the first electrode, the second electrode and the dielectric body form a capacitor.

According to another aspect of the present invention, a method for manufacturing a sensor includes forming a first electrode including a metal film on a first printed wiring board, forming a second electrode including a metal film on a second printed wiring board, laminating an adhesive film having an opening portion on the first printed wiring hoard such that the opening portion is aligned to expose the first electrode, and laminating the second printed wiring board on the adhesive film such that the second electrode faces the first electrode in the opening portion of the adhesive layer and the first electrode and the second electrode are spaced apart by a dielectric body and form a capacitor.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a top view schematically showing an example of a sensor according to the present invention.

FIG. 2 is a cross-sectional view (cross-sectional view taken at the A-A line in FIG. 1) schematically showing an example of the structure of a capacitor that forms a sensor of the present invention;

FIG. 3 is a cross-sectional view schematically showing an example of the structure of a capacitor where insulative film is formed on the upper surface of an electrode;

FIG. 4 is a cross-sectional view schematically showing an example of the structure of a capacitor having through-hole conductors electrically connected to the first electrode and the second electrode respectively;

FIG. 5 is a cross-sectional view schematically showing an example of a keyboard which includes a sensor of the present invention;

FIG. 6 is a cross-sectional view schematically showing another example of a keyboard which includes a sensor of the present invention;

FIGS. 7A, 7B, 7C, 7D and 7E are views of steps schematically showing an example of the process for manufacturing a sensor according to the present invention;

FIGS. 8A, 8B, 8C and 8D are views of steps schematically showing an example of the process for manufacturing a sensor according to the present invention;

FIG. 9A-1 is a top view schematically showing an adhesive film, and FIG. 9A-2 is a top view schematically showing an adhesive film having openings formed at predetermined locations;

FIG. 9B-1 is a cross-sectional view schematically showing a first printed wiring board, and FIG. 9B-2 is a top view of the first printed wiring board shown in FIG. 9B-1;

FIG. 9C-1 is a top view of the state in which adhesive film is laminated on the first printed wiring board, and FIG. 9C-2 is a cross-sectional view shown in FIG. 9C-1;

FIG. 9D-1 is a cross-sectional view schematically showing a second printed wiring board, and FIG. 9D-2 is a top view of the second printed wiring board shown in FIG. 9D-1;

FIG. 9E-1 is a top view schematically showing a state in which the first printed wiring board and the second printed wiring board are pressed and integrated, and FIG. 9E-2 is a cross-sectional view of the state shown in FIG. 9E-1;

FIG. 10 is a cross-sectional view schematically showing an example of the structure of a capacitor where a space as a dielectric body is formed in the first printed wiring board;

FIG. 11 is a cross-sectional view schematically showing an example of the structure of a capacitor where penetrating holes connected to the space are formed in the first printed wiring board and the second printed wiring board;

FIG. 12A-1 is a cross-sectional view schematically showing low-flow prepreg, and FIG. 12A-2 is a cross-sectional view schematically showing low-flow prepreg with a penetrating hole formed at a predetermined location;

FIG. 12B is a cross-sectional view schematically showing copper foil;

FIG. 12C is a cross-sectional view schematically showing a second printed wiring hoard;

FIG. 12D is a cross-sectional view schematically showing a state in which the second printed wiring board, low-flow prepreg and copper foil are laminated and pressed;

FIG. 12E is a cross-sectional view schematically showing a state in which a first electrode is formed;

FIG. 12F is a cross-sectional view schematically showing a state in which penetrating holes connected to the space are formed;

FIGS. 13A, 13B and 13C are cross-sectional views schematically showing examples of the structures of a capacitor in which an insulation layer is formed as a dielectric body between the first electrode and the second electrode;

FIGS. 14A and 14B are cross-sectional views schematically showing examples of a sensor having a reference capacitor according to the present invention;

FIG. 15 is a top view schematically showing an example of the structure of capacitors that can be used as an angle sensor;

FIG. 16 is a cross-sectional view taken at the B-B line in the structure of the capacitors shown in FIG. 15;

FIG. 17 is a cross-sectional view schematically showing a state when the capacitors with the structure shown in FIG. 16 are inclined;

FIG. 18 is a top view schematically showing an example of a state in which sensor control circuits are connected to a sensor of the present invention; and

FIG. 19 is a top view schematically showing another example of a state in which a sensor control circuit is connected to a sensor of the present invention.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

The following describes a sensor, a keyboard and a method for manufacturing the sensor according to the first embodiment of the present invention.

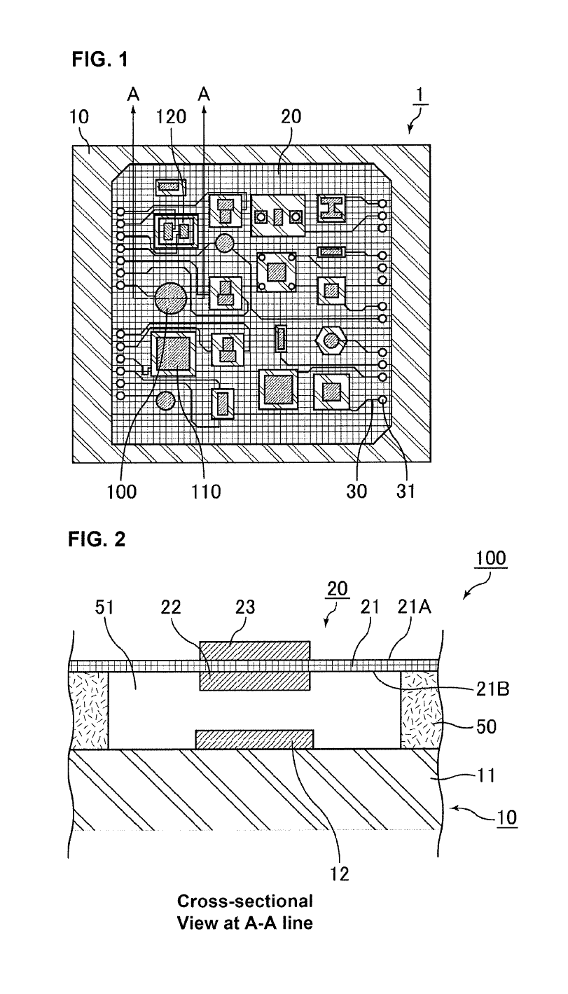

FIG. 1 is a top view schematically showing an example of a sensor of the present invention. Sensor 1 shown in FIG. 1 includes first printed wiring board 10, which is a rigid printed wiring board, and second printed wiring board 20, which is a flexible printed wiring board and is positioned on the upper surface of first printed wiring board 10. An adhesive layer is arranged in a partial portion between first printed wiring board 10 and second printed wiring board 20. First printed wiring board 10 and second printed wiring board 20 are adhered to the adhesive layer so that their positional relationship is fixed. Wiring formed in first printed wiring board 10 and second printed wiring board 20 is extended to the outside through extension wiring 30. Signals are connected to the outside of sensor 1 through pad 31. As a method for connecting the sensor to the outside, a via conductor, conductive paste, soldering or the like is used.

A first electrode is formed in first printed wiring board 10 and a second electrode is formed in second printed wiring board 20, and the first electrode faces the second electrode. A dielectric body that includes an insulation layer or space exists between the first electrode and the second electrode. A capacitor is formed with the dielectric body and with the first electrode and the second electrode sandwiching the dielectric body. A sensor according to the present embodiment works as a sensor by sensing a change in the capacitance of the capacitor. A detailed description of the structure of the capacitor is provided later.

Multiple types of sensors are formed in sensor 1. In the sensor shown in FIG. 1, pressure sensor 100, humidity sensor 110, angle sensor 120 and the like are formed on a substrate. Those sensors have the above-described capacitors, and each capacitor works as a pressure sensor, a humidity sensor or an angle sensor by sensing a change in the capacitance of the capacitor.

FIG. 2 is a cross-sectional view schematically showing an example of the structure of a capacitor forming a sensor of the present invention (a cross-sectional view taken at the A-A line in FIG. 1). FIG. 2 shows a schematic structure of a capacitor in pressure sensor 100.

First printed wiring board 10 is formed with substrate 11 and conductive circuits made of metal film formed on substrate 11. FIG. 2 shows first electrode 12 which is part of the conductive circuits. Substrate 11 relating to the present embodiment is a rigid substrate. The metal film is not limited to a specific type, but it is preferred to be made of electroless copper-plated film and electrolytic copper-plated film.

Second printed wiring board 20 is formed with substrate 21, conductive circuits which are formed, among the surfaces of substrate 21, on second surface (21B) facing first printed wiring board 10, and dummy circuits which are formed, among the surfaces of substrate 21, on first surface (21A) opposite second surface (21B). Substrate 21 of the present embodiment is a flexible substrate (such as a polyimide film substrate). FIG. 2 shows second electrode 22 which is part of the conductive circuits formed on second surface (21B), and dummy electrode 23 which is part of the dummy conductive circuits formed on first surface (21A). If a dummy conductive circuit and a dummy electrode are formed, forces exerted on both surfaces of the second printed wiring board, which is a flexible printed wiring board, are balanced. Thus, warping of the second printed wiring board is prevented.

First printed wiring board 10 and second printed wiring board 20 are adhered by adhesive layer 50 arranged between them. Adhesive layer 50 adheres a portion between first printed wiring board 10 and second printed wiring board 20. The portion where adhesive layer 50 is not formed between first printed wiring board 10 and second printed wiring board 20 is set as space 51. Space 51 works as a dielectric body.

Since first electrode 12 and second electrode 22 face each other by sandwiching space 51 as a dielectric layer, they work as a capacitor. Capacitance (C) of the capacitor is indicated as formula (1) below:

C=∈S/d (1)

(C: capacitance, ∈: dielectric constant of dielectric body, S: the area of electrodes, d: distance between electrodes)

As understood from formula (1) above, capacitance changes when distance (d) is changed between the first electrode and the second electrode. When pressure is exerted on second printed wiring board 20, which is a flexible printed wiring board, since the flexible printed wiring board is elastic, second printed wiring board 20 warps, leading to a change in the position of second electrode 22. As a result, distance (d) is changed between first electrode 12 and second electrode 22, leading to a change in capacitance accordingly. Namely, when second printed wiring board 20 is pressed from the upper side, distance (d) is reduced, and capacitance changes in the plus direction. Then, when the pressure exerted on second printed wiring board 20 is released, due to its elasticity the flexible wiring board returns to its original pre-pressure position, and the position of second electrode 22 is changed again, increasing distance (d) (returns to its original value), and the capacitance decreases (returns to its original value). By sensing such fluctuation in capacitance, the above capacitor works as a pressure sensor which measures the pressure exerted on second printed wiring board 20.

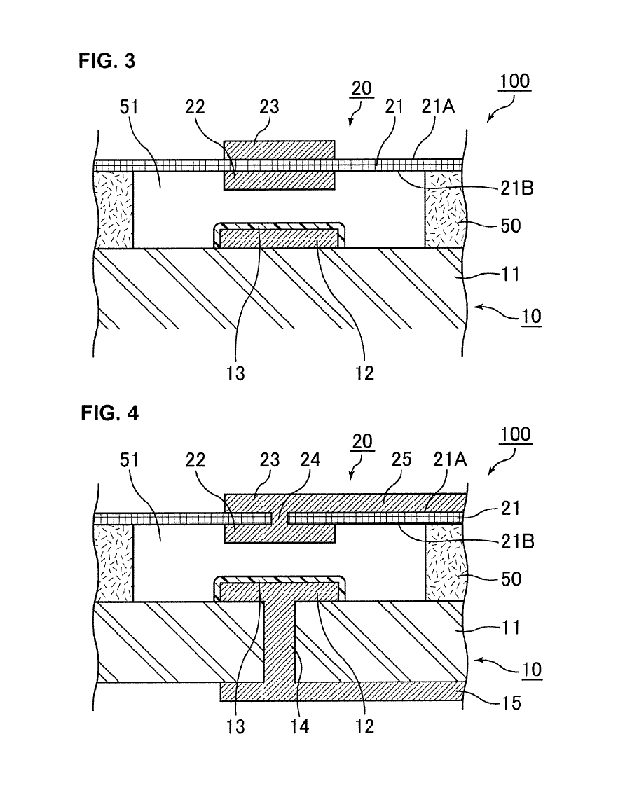

FIG. 3 is a cross-sectional view schematically showing an example of the structure of a capacitor where insulative film is formed on the upper surface of an electrode. In the example shown in FIG. 3, insulative film 13 is formed on the upper surface of first electrode 12 shown in FIG. 2. When insulative film 13 is formed on first electrode 12, even if pressure is exerted on the sensor and the distance is reduced between first electrode 12 and second electrode 22, short circuiting is prevented between electrodes. In addition, insulative film 13 also works as a dielectric body between the electrodes. Also, insulative film 13 works as an antioxidation film of first electrode 12.

As the material for insulative film, materials usable for interlayer resin insulation layers of a multilayer printed wiring board may be used preferably. For example, the following resin materials are listed: BCB (benzo-cyclo-butene), epoxy resin, polyimide resin, polyphenylene ether resin, polyolefin-type resin, fluororesin, thermoplastic elastomer and the like. Among those, epoxy resin is especially preferred.

FIG. 3 shows an example in which insulative film 13 is formed on the upper surface of first electrode 12. However, insulative film may be formed on both the upper surface of first electrode 12 and on the upper surface of second electrode 22. Alternatively, insulative film may be formed only on the upper surface of second electrode 22. In any case, short circuiting is prevented between the electrodes when the distance is reduced between first electrode 12 and second electrode 22.

FIG. 4 is a cross-sectional view schematically showing an example of the structure of a capacitor having through-hole conductors electrically connected to the first electrode and the second electrode respectively. In the example shown in FIG. 4, through-hole conductor 14 is formed in first printed wiring board 10, and through-hole conductor 14 is electrically connected to first electrode 12 on the upper surface of substrate 11. Through-hole conductor 14 is electrically connected to wiring 15 on the lower-surface side of substrate 11 (the surface opposite the upper surface).

Also, through-hole conductor 24 is formed in second printed wiring board 20, and through-hole conductor 24 is electrically connected to second electrode 22 formed on second surface (21B) of substrate 21. Through-hole conductor 24 is connected to conductive pattern 23 on the first-surface (21A) side of substrate 21. Conductive pattern 23 is electrically connected to wiring 25.

According to such a structure, the capacitor and external wiring are electrically connected by through-hole conductor 14 and wiring 15 as well as by through-hole conductor 24 and wiring 25. Therefore, the electric capacity of the capacitor is measured at the external wiring.

FIG. 4 shows an example in which through-hole conductors are formed in both first printed wiring board 10 and second printed wiring board 20. However, a though-hole conductor may be formed only in first printed wiring board 10, or only in second printed wiring board 20.

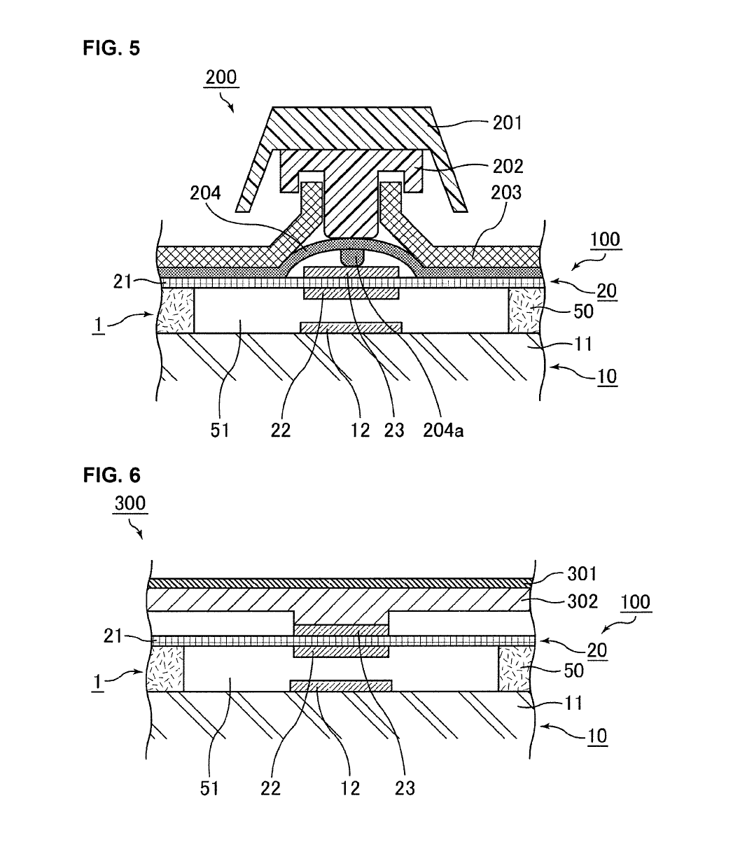

Next, a keyboard according to the present embodiment is described. FIG. 5 is a cross-sectional view schematically showing an example of a keyboard which includes a sensor of the present invention. FIG. 5 schematically shows part of a keyboard for desktop personal computers. In keyboard 200 shown in FIG. 5, components such as a key top are arranged in the position corresponding to pressure sensor 100 of sensor 1 relating to the present embodiment.

In particular, protruding portion (204a) of rubber component 204 makes contact with dummy electrode 23 of sensor 1 shown in FIG. 1, and piston component 202 and key top 201 are arranged on rubber component 204 in that order. Piston component 202 and key top 201 are supported by mold 203. When key top 201 is pressed, piston component 202 is pushed down while protruding portion (204a) of rubber component 204 is also pushed down, second printed wiring board 20 warps, and the position of second electrode 22 is changed. Then, since the capacitance of the capacitor changes, which key is pressed down is detected from the change in capacitance. When the pressure exerted on key top 201 is released, positions of key top 201 and the like are returned to their original positions due to the rebounding force of the rubber component, and second electrode 22 returns to its original position.

FIG. 6 is a cross-sectional view schematically showing another example of a keyboard having a sensor according to the present invention. FIG. 6 schematically shows part of a touch panel. In the present application, a touch panel as an input device is included in the keyboard. At touch panel 300, upper electrode sheet 302 made of PET film and plastic film is positioned along with hard-coat film 301 in the portion corresponding to pressure sensor 100, which is sensor 1 according to the present embodiment. When pressure is exerted on the surface of hard-coat film 301, the pressure is exerted on second printed wiring board 20 through upper electrode sheet 302.

Accordingly, second printed wiring board 20 warps, leading to a change in the position of second electrode 22. Then, the capacitance of the capacitor changes. By arranging multiple pressure sensors 100 in a lattice, for example, which part of the touch panel is pressed is determined from the change in capacitance. Also, by measuring the change in the capacitance of each of adjacent multiple pressure sensors 100, the movement of a fingertip tracing on the touch panel is detected.

Next, a method for manufacturing a sensor according to the present embodiment is described with reference to the drawings. The method for manufacturing a sensor according to the present embodiment includes the following: preparing a first substrate; manufacturing a first printed wiring board by forming a first electrode made of metal film on the first substrate; preparing a second substrate; manufacturing a second printed wiring board by forming a second electrode made of metal film on the second substrate; forming insulative film on a surface of the first electrode; preparing adhesive film having an opening at a predetermined location; laminating the adhesive film on the first printed wiring board by aligning the opening with the position of the first electrode; and laminating and pressing the second printed wiring board on the adhesive film by aligning the second electrode with the position of the opening.

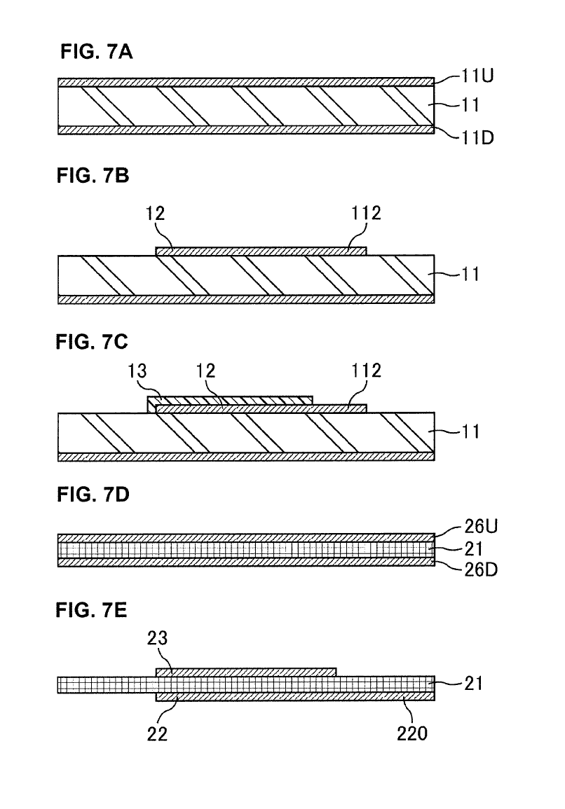

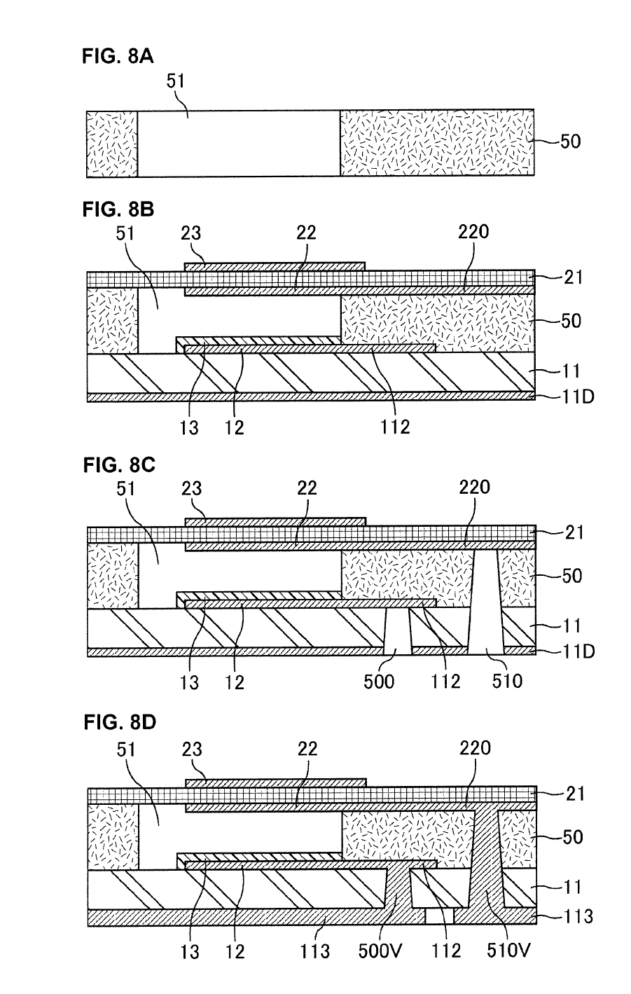

An example of the method for manufacturing a sensor of the embodiment is shown in FIGS. 7A, 7B, 7C, 7D and 7E, and in FIGS. 8A, 8B, 8C and 8D.

(1) A double-sided copper-clad laminate is prepared, being made of first substrate 11 and metal foils (11U, 11D) laminated on both surfaces of the substrate (FIG. 7A). The first substrate has a first surface and a second surface opposite the first surface. As for metal foil (11U) on the first surface of the first substrate, copper foil and nickel foil are listed. As for metal foil (11D) on the second surface of the first substrate, copper foil and nickel foil are listed. As for the first substrate, it is not limited to any particular type. For example, the following resin substrates are listed: a substrate including glass fiber as core material (such as glass epoxy resin), bismaleimide-triazine (BT) resin substrate, RCC substrate and the like.

(2) First electrode 12 is formed from metal foil (11U) using a subtractive method (FIG. 7B). Other than first electrode 12, first conductive circuit 112 is formed on the first surface of the first substrate. First substrate 11 may have first conductive circuit 112 on the first surface.

(3) Resin material is formed on first electrode 12 using a coating method. The resin material is dried and insulative film 13 is formed on first electrode 12 (FIG. 7C).

(4) A flexible substrate made of metal foils (26U, 26D) and second substrate 21 is prepared (FIG. 7D). The second substrate has a first surface and a second surface opposite the first surface, and metal foil (26U) is formed on the first surface and metal foil (26D) is formed on the second surface. As an example for second substrate 21, polyimide film substrate, PET (polyethylene terephthalate) film substrate, epoxy resin film substrate and the like are listed.

(5) On the second surface of second substrate 21, second electrode 22 is formed from metal foil (26D) using a subtractive method (FIG. 7E). The second substrate may have second conductive circuit 220 on its second surface. Second substrate 21 may have dummy electrode 23 on its first surface. When the second substrate includes a dummy electrode. the second substrate is suppressed from warping and becomes flat.

(6) Adhesive film 50 having penetrating hole 51 is prepared (FIG. 8A). As for the adhesive film, a low-flow type prepreg is preferred.

(7) First substrate 11 and second substrate 21 are laminated via adhesive film 50, and they are integrated by thermal pressing (FIG. 8B). The first surface of first substrate 11 faces the second surface of second substrate 21. Also, first electrode 12 faces second electrode 22, and is positioned in space 51. Adhesive film 50 becomes adhesive layer 50.

(8) A laser is irradiated at first substrate 11 from the second-surface side of first substrate 11. Opening 500 is formed in first substrate 11 to reach first conductive circuit 112 formed on the first surface of first substrate 11. A laser is irradiated at first substrate 11 and adhesive layer 50 from the second-surface side of first substrate 11. Opening 510 is formed in first substrate 11 and adhesive layer 50 to reach second conductive circuit 220 formed on the second surface of second substrate 21 (FIG. 8C).

(9) Via conductors (500V, 510V) are formed in opening 500 and opening 510. Then, conductive circuit 113 is formed on the second surface of first substrate 11 (FIG. 8D). First electrode 12 and conductive circuit 113 on the second surface of the first substrate are connected through via conductor (500V). Also, second electrode 22 and first conductive circuit 113 on the second surface of the first substrate are connected through via conductor (510V). The capacitance between first electrode 12 and second electrode 22 is easily measured. In the embodiment shown in FIG. 8D, a through-hole conductor (via conductor 500V) electrically connected to first electrode 12 and a through-hole conductor (via conductor 510V) electrically connected to second electrode 22 are both formed in first printed wiring board 10.

As for adhesive sheet material (adhesive film), low-flow epoxy resin film, prepreg and the like are listed.

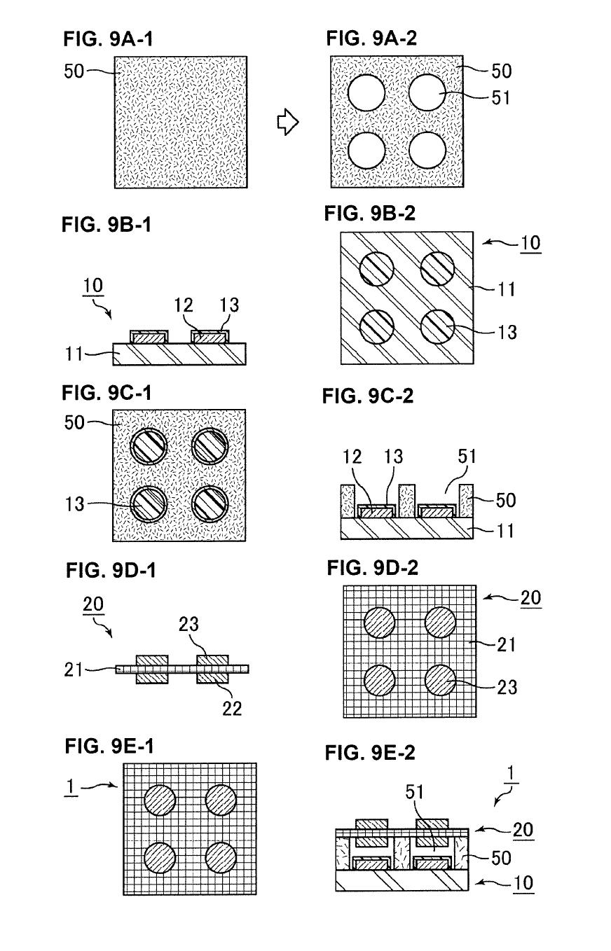

Views of steps focusing on the manufacturing process of a capacitor relating to a sensor of the present embodiment are shown in FIGS. 9A-1, 9A-2, 9B-1, 9B-2, 9C-1, 9C-2, 9D-1, 9D-2, 9E-1 and 9E-2. FIG. 9A-1 is a top view schematically showing an adhesive film and FIG. 9A-2 is a top view schematically showing the adhesive film having openings formed at predetermined locations. FIG. 9B-1 is a cross-sectional view schematically showing a first printed wiring board, and FIG. 9B-2 is a top view of the first printed wiring board shown in FIG. 9B-1. FIG. 9C-1 is a cross-sectional view schematically showing a state in which an adhesive film is laminated on the first printed wiring board, and FIG. 9C-2 is a top view of the state shown in FIG. 9C-1. FIG. 9D-1 is a cross-sectional view schematically showing a second printed wiring board, and FIG. 9D-2 is a top view of the second printed wiring board shown in FIG. 9D-1. FIG. 9E-1 is a top view schematically showing a state in which the first printed wiring board and the second printed wiring board are integrated through pressing, and FIG. 9E-2 is a cross-sectional view of the state shown in FIG. 9E-1.

(10) Opening 51 is formed at a predetermined location of adhesive film 50 as shown in FIG. 9A-1 by blanking or the like (see FIG. 9A-2). The position and size of opening 51 are determined considering the positions and sizes of first electrode 12 and second electrode 22. In particular, the position and size of opening 51 are determined in such a way that opening 51 is set as space 51 between first electrode 12 and second electrode 22 (see FIGS. 2 and 3).

(11) First printed wiring board 10 is prepared as shown in FIGS. 9B-1 and 9B-2 through the above steps (1)˜(3). Opening 51 of adhesive film 50 formed in the above step (10) is aligned with the position of first electrode 12 in first printed wiring board 10. Then, adhesive film 50 is laminated on first printed wiring board 10. In FIGS. 9C-1 and 9C-2, adhesive film 50 is laminated on first printed wiring board 10.

(12) Second printed wiring board 20 is prepared as shown in FIGS. 9D-1 and 9D-2 through the above steps (4)˜(5). Opening 51 of adhesive film 50 laminated on first printed wiring board 10 in above step (11) is aligned with second electrode 22 of second printed wiring board 20. and second printed wiring board 20 is laminated on adhesive film 50. Then, first printed wiring board 10, adhesive film 50 and second printed wiring board 20 are thermal pressed, and first printed wiring board 10, adhesive film 50 and second printed wiring board 20 are integrated. The adhesive film is cured and adhesive layer 50 is formed between first printed wiring board 10 and second printed wiring board 20. Opening 51 of adhesive film 50 becomes space 51. Sensor 1 shown in FIGS. 9E-1 and 9E-2 is manufactured through the above steps.

The sensor shown in FIG. 4 has a via conductor and a through-hole conductor. Such via conductor and through hole conductor are manufactured by the same method as the method used for manufacturing a printed wiring board.

The following (1) through (10) list some of the characteristics of a sensor, a keyboard and a method for manufacturing the sensor according to the first embodiment.

(1) In a sensor according to the present embodiment, a first printed wiring board and a second printed wiring board are positioned to face each other, and electrodes for forming a capacitor are positioned to face their respective printed wiring boards. Then, a dielectric body is positioned between the two electrodes. According to such a structure, the capacitance of a capacitor is determined by the distance between the first electrode and the second electrode along with the dielectric constant of the dielectric body. Since the distance between the first electrode and the second electrode substantially corresponds to the distance between the first printed wiring board and the second printed wiring board, a sensor is obtained to have a predetermined level of capacitance by setting the distance at a predetermined value between the first printed wiring board and the second printed wiring board. As a result, a simplified and inexpensive sensor is obtained without requiring a semiconductor manufacturing process or MEMS technology.

(2) In a sensor according to the present embodiment, the second printed wiring board is a flexible printed wiring board. Since a flexible printed wiring board warps when it receives pressure, the position of an electrode arranged in the flexible wiring board is easily changed in response to pressure, leading to a change in the distance between electrodes. Capacitance changes in response to such a change. As a result, a simplified and inexpensive sensor is obtained without requiring a semiconductor manufacturing process or MEMS technology.

(3) In a sensor according to the present embodiment, a second electrode is formed on a second surface of the second printed wiring board, which is a flexible printed wiring board, and a dummy electrode is formed on a first surface opposite the second surface. The pattern of the dummy electrode is the same as that of the second electrode. Therefore, warping of the flexible printed wiring board is reduced.

(4) In a sensor according to the present embodiment, a second printed wiring board, which is a flexible printed wiring board, is elastic. Since an elastic printed wiring board warps when it receives pressure, the position of an electrode arranged in the elastic printed wiring board is easily changed in response to pressure. As a result, the distance is changed between electrodes, leading to a change in capacitance. As a result, a simplified and inexpensive sensor is obtained without requiring a semiconductor manufacturing process or MEMS technology.

(5) In a sensor according to the present embodiment, the capacitance changes in response to a change in the distance between the first electrode and the second electrode. Therefore, the sensor according to the present embodiment works as a pressure sensor.

(6) A sensor according to the present embodiment includes insulative film on the top surface of a first electrode or the top surface of a second electrode. When insulative film is formed on an electrode, short circuiting between electrodes is prevented. Insulative film also works as a dielectric body between the electrodes. In addition, insulative film works as antioxidation film for the electrode.

(7) A sensor according to the present embodiment includes an adhesive layer between a first printed wiring board and a second printed wiring board so that the first printed wiring board and the second printed wiring board are adhered. Then the adhesive layer has an opening to expose a first electrode and a second electrode. When the first printed wiring board and the second printed wiring board are adhered, the distance between the first printed wiring board and the second printed wiring board is determined by the thickness of the adhesive layer. In addition, the space in the opening of the adhesive layer becomes a dielectric body. According to such a structure, since the thickness of the space as a dielectric body is the same as the thickness of the adhesive layer, the thickness of the dielectric body is controlled by adjusting the thickness of the adhesive layer. Therefore, a capacitor with predetermined capacitance is obtained.

(8) In a sensor according to the present embodiment, a through-hole conductor electrically connected to a first electrode may be formed in a first printed wiring board, and a through-hole conductor electrically connected to the second electrode may be formed in a second printed wiring board. When a through-hole conductor is formed to be electrically connected to an electrode of a capacitor, the capacitor is electrically connected to external wiring through the through-hole conductor. Therefore, the capacitance of the capacitor is easily distributed to the outside.

(9) A keyboard according to the present embodiment includes a capacitor of the present embodiment which is suitable for working as a sensor by sensing a change in capacitance. Therefore, a capacitor according to the present embodiment is used preferably as a component in a keyboard.

(10) A method for manufacturing a sensor according to the present embodiment includes the following: preparing a first substrate; manufacturing a first printed wiring board by forming a first electrode made of metal film on the first substrate; preparing a second substrate; manufacturing a second printed wiring board by forming a second electrode made of metal film on the second substrate; forming insulative film on a surface of the first electrode; preparing adhesive film having an opening at a predetermined location: laminating the adhesive film on the first printed wiring board by aligning the opening with the position of the first electrode; and laminating and pressing the second printed wiring board on the adhesive film by aligning the second electrode with the position of the opening.

### Second Embodiment

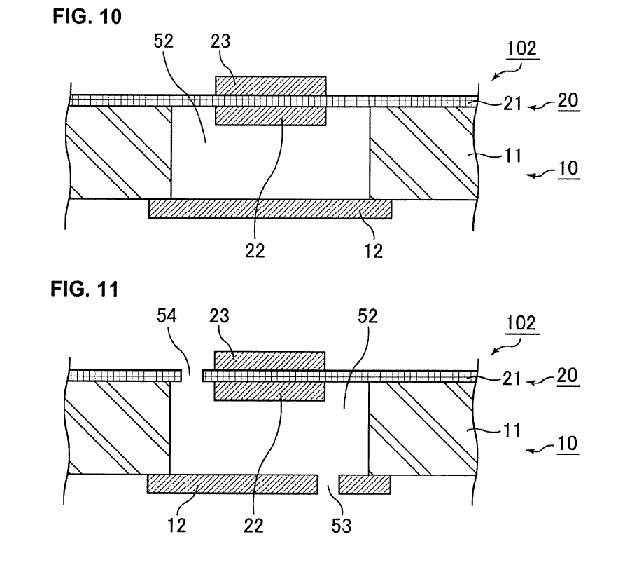

The following shows a sensor, a keyboard and a method for manufacturing a sensor according to the second embodiment of the present invention. FIG. 10 schematically shows the structure of a capacitor that forms pressure sensor 102 according to the second embodiment.

In a sensor according to the second embodiment of the present invention, space 52 as a dielectric body is a penetrating hole formed in substrate 11 of first printed wiring board 10. Namely, the space is not formed between first printed wiring board 10 and second printed wiring board 20, but is formed in first printed wiring board 10. For that matter, a sensor according to the second embodiment is different from a sensor according to the first embodiment.

In addition, there is no adhesive layer formed between first printed wiring board 10 and second printed wiring board 20, and first printed wiring board 10 and second printed wiring board 20 are directly adhered. The rest of the structure of a sensor according to the second embodiment is the same as that of a sensor according to the first embodiment.

A penetrating hole to become space 52 is formed in substrate 11 of first printed wiring board 10, and first electrode 12 is formed on the second surface of substrate 11. In the first embodiment, first electrode 12 is formed on the first surface of first substrate 11.

The structure of second printed wiring board 20 is the same as that of second printed wiring board 20 of sensor 1 according to the first embodiment. Second electrode 22 is positioned in space 52 formed in substrate 11 of first printed wiring board 10.

First electrode 12, second electrode 22 and space 52 work as a capacitor in the above structure as well. Accordingly, a sensor according to the present embodiment works as a sensor by sensing a change in the capacitance of the capacitor.

FIG. 11 is a cross-sectional view schematically showing an example of the structure of a capacitor where penetrating holes connected to the space are formed in the first printed wiring board and the second printed wiring board. In the example shown in FIG. 11, penetrating hole 53 connected to space 52 is formed in first electrode 12, and penetrating hole 54 connected to space 52 is formed in substrate 21. According to such a structure, when the air in the space is heated and expanded during a reflow, the expanded air exits through the penetrating holes. Therefore, the electrodes are prevented from being removed from the printed wiring boards. In addition, the penetrating holes may be filled after the reflow.

In the structure of the capacitor shown in FIGS. 10 and 11, insulative film is not formed on the first electrode or the second electrode. However, the same as in the first embodiment, insulative film may be formed on the first electrode or the second electrode.

A keyboard is manufactured having the same functions as those in the first embodiment using a sensor according to the present embodiment.

The following describes a method for manufacturing a sensor according to the present embodiment.

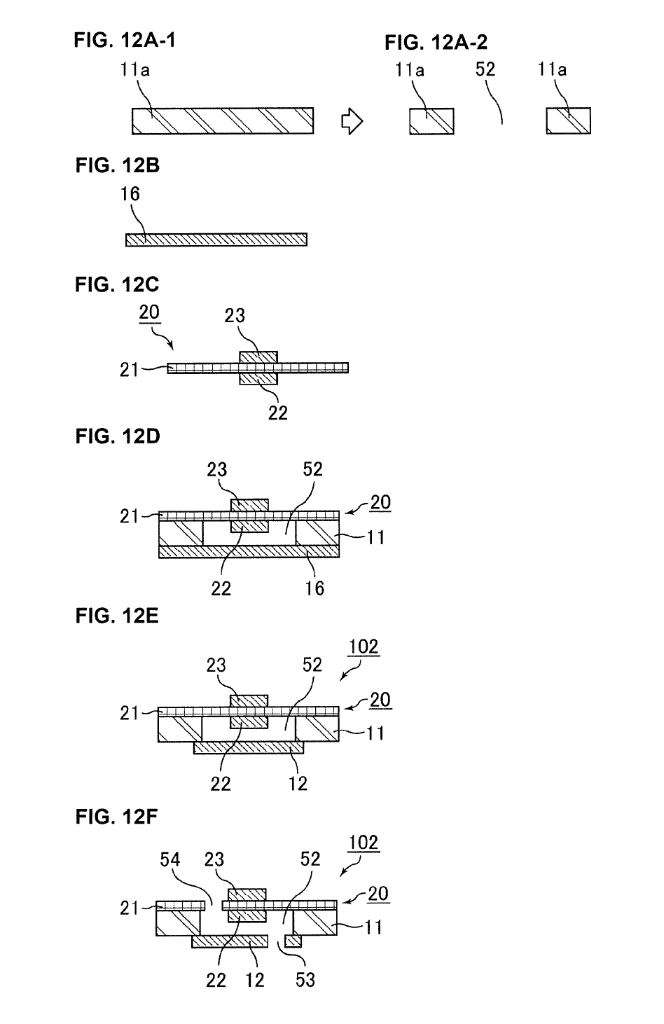

Low-flow prepreg (11a) is prepared (FIG. 12A-1). Penetrating hole 52 is formed at a predetermined location of low-flow prepreg (11a) (FIG. 12A-2). Copper foil 16 is prepared (FIG. 12B). Second printed wiring board 20 is formed the same as in the first embodiment (FIG. 12C). Second printed wiring board 20, low-flow prepreg (11a) and copper foil 16 are integrated through thermal pressing (FIG. 12D). First electrode 12 is formed from copper foil 16 (FIG. 12E). Penetrating holes (53, 54) are formed to be connected to space 52 (FIG. 12F).

In a method for manufacturing a sensor according to the present embodiment, prepreg is used as the material for the substrate of a first printed wiring board. As for the prepreg, low-flow prepreg with less resin flow is preferred to be used. By thermal pressing the prepreg, copper foil and the second printed wiring board, forming the first printed wiring board and adhering the first printed wiring board and the second printed wiring board are simultaneously conducted. An adhesive layer is not required between the first printed wiring board and the second printed wiring board in this method.

However, it is not always required to form penetrating hole 53, which is formed in first electrode 12 and connected to space 52. Also, it is not always required to form penetrating hole 54, which is formed in substrate 21 and connected to space 52. Laser processing, drill processing and the like are listed as methods for forming the penetrating hole. FIG. 11 shows the structure of pressure sensor 102 having penetrating holes.

A sensor, a keyboard and a method for manufacturing a sensor according to the second embodiment show the same characteristics (1)˜(6), (9) and (10) as in the first embodiment. Furthermore, a sensor, a keyboard and a method for manufacturing a sensor according to the second embodiment show the following characteristics.

(11) In a sensor according to the present embodiment, the space as a dielectric body is a penetrating hole formed in the substrate of a first printed wiring board. In such a structure as well, a first electrode, a second electrode and the space work as a capacitor. Accordingly, a sensor according to the present embodiment works as a sensor by sensing a change in the capacitance of the capacitor.

(12) In a sensor according to the present embodiment, a penetrating hole connected to the space is formed in the first printed wiring board or the second printed wiring board. According to such a structure, when the air in the space is heated and expanded during the reflow, the expanded air exits through the penetrating hole. Therefore, electrodes are prevented from being removed from the printed wiring boards.

### Third Embodiment

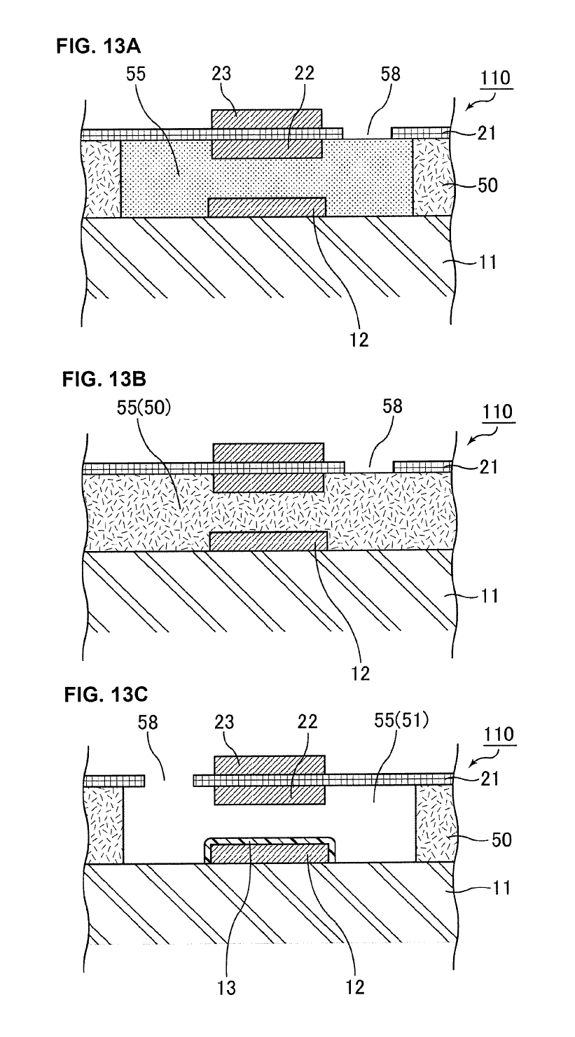

The following shows a sensor and a method for manufacturing a sensor according to the third embodiment of the present invention. FIGS. 13A, 13B and 13C each show the schematic structure of a capacitor of humidity sensor 110 according to the third embodiment. In the humidity sensor shown in FIG. 13A, insulation layer 55 as the dielectric body is formed between first electrode 12 and second electrode 22. In the humidity sensor shown in FIG. 13A, a different material from adhesive layer 50 is used for insulation layer 55. In the humidity sensor shown in FIG. 13B, insulation layer 55 as the dielectric body is made of the same material as that of adhesive layer 50. In such a case, the manufacturing process is simplified. In the humidity sensor shown in FIG. 13C, insulation layer 55 as the dielectric body is space 51.

In a sensor according to the third embodiment of the present invention, the dielectric body is the insulation layer filled in a portion which is the space in the structure of a capacitor according to the first embodiment. As shown in the above formula (I), since the capacitance of the capacitor is affected by the dielectric constant of the dielectric body existing between the electrodes, the capacitance of the capacitor formed in a sensor of the present embodiment is set by the dielectric constant of the insulation layer.

In a sensor according to the present embodiment, it is preferred to use a material for the insulation layer that tends to absorb moisture in the air and its dielectric constant tends to change in response to a change in the amount of the absorbed moisture. If such a material is used, since the capacitance changes in response to a change in humidity, a sensor of the present embodiment works as a humidity sensor. That is because a sensor according to the present embodiment senses a change in humidity from the change in capacitance.

As an example of a preferable material for the dielectric body of a sensor in the present embodiment, the following may be listed: epoxy resin, BCB (benzo-cyclo-butene), cellulose polymers such as cellulose acetate hydrogen phthalate, cellulose acetate and cellulose propionate, polyvinyl alcohol, polyvinyl acetate, polyethylene glycol, polypropylene glycol, polyamide, phenol resin, crosslinked polymers of methacrylate monomers, crosslinked polymers of fluorinated polyimide and the like. In addition, the dielectric body may be air (space).

As for a humidity sensor, it is preferred that air, which is the subject for measuring humidity, be kept in touch with the dielectric body. Therefore, hole 58 or slit 58 connected to the dielectric body (see FIGS. 13A, 13B and 13C) is preferred to be formed.

Since the structure of a sensor according to the third embodiment of the present invention is the same as that in the first embodiment except that the structure of the dielectric body is different, a detailed description of the rest is omitted here.

By forming an insulation layer in a penetrating hole formed in the substrate of a first printed wiring board in the second embodiment, a capacitor that functions as a humidity sensor is manufactured. Also, a sensor according to the third embodiment may have a through-hole conductor electrically connected to the first electrode or the second electrode of a capacitor that functions as a humidity sensor.

A sensor according to the present embodiment is manufactured by arranging an adhesive layer between the first electrode and the second electrode and between the first printed wiring board and the second printed wiring board, and by thermal pressing them. Alternatively, a sensor according to the present embodiment is manufactured by injecting a liquid-type material (material for making an insulation layer) into the space through a penetrating hole in the sensor shown in FIG. 12F and by adding heat. Yet alternatively, a humidity sensor may be manufactured by forming a hole or a slit to be connected to the space in the sensor according to the first embodiment.

A sensor and a method for manufacturing a sensor according to the third embodiment show the same characteristics (1), (3), (6), (8), (10) and (11) as in the first and second embodiments, along with the following characteristics.

(13) In a sensor according to the present embodiment, the capacitance changes when the dielectric constant of the dielectric body is changed in response to a change in humidity. Thus, the sensor of the present embodiment functions as a humidity sensor.

(14) A sensor according to the present embodiment includes an adhesive layer between a first printed wiring board and a second printed wiring board so as to adhere the first printed wiring board and the second printed wiring board. The adhesive layer may also be present between the first electrode and the second electrode. When the first printed wiring board and the second printed wiring board are adhered, the distance between the first printed wiring board and the second printed wiring board is set by the thickness of the adhesive layer. Then, the capacitance of the capacitor is set at a predetermined value.

### Fourth Embodiment

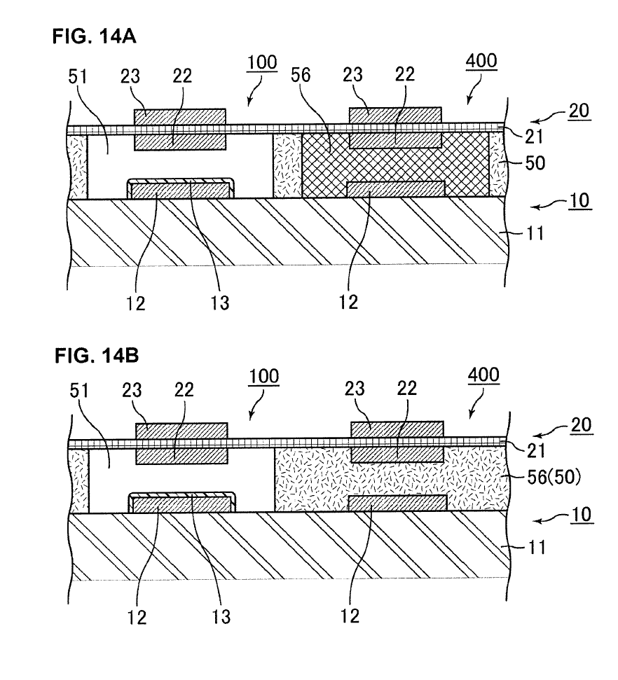

The following shows a sensor and a method for manufacturing a sensor according to the fourth embodiment of the present invention. FIGS. 14A and 14B are cross-sectional views schematically showing an example of a sensor having a reference capacitor. The sensor shown in FIG. 14A has pressure sensor 100 and reference capacitor 400. Pressure sensor 100 has the same structure as that described in the first embodiment (see FIG. 2).

Reference capacitor 400 shown in FIG. 14A is a capacitor formed with first electrode 12 of first printed wiring board 10, second electrode 22 of second printed wiring board 20 and space filler 56 as a dielectric body. In reference capacitor 400, the space between first electrode 12 and second electrode 22 is filled with space filler 56. Therefore, if pressure is exerted on second electrode 22, the distance between the first electrode and the second electrode does not change, and the capacitance of reference capacitor 400 does not change. Space filler 56 may be the same material as that for adhesive layer 50 (see FIG. 14B).

In addition, as for space filler 56, which is the dielectric body of reference capacitor 400, the following material is preferred: a material whose dielectric constant does not change or shows little change in response to a change in the external environment such as temperature and humidity. Thus, the capacitance does not change even when the external environment is changed.

Namely, reference capacitor 400 is a capacitor that has substantially a constant capacitance, indicating its capacitance does not change or shows little change with or without pressure or in response to a change in the external environment. The substantially constant value of capacitance of the reference capacitor is used as the base value of the capacitance.

Pressure sensor 100 and reference capacitor 400 are adjacent to each other and are formed using the same first printed wiring board 10 and second printed wiring board 20. Since the distance between first printed wiring board 10 and second printed wiring board 20 is set by the thickness of adhesive layer 50, in pressure sensor 100 and reference capacitor 400, distances between their respective first electrodes 12 and second electrodes 22 are the same.

When sensors according to the present embodiment are manufactured, the thicknesses of adhesive layers are different because the thickness of adhesive film differs depending on each lot. Therefore, between the sensors in which different adhesive films are used, the initial value of capacitance of a pressure sensor (the capacitance when no pressure is exerted) varies. When the capacitance of a capacitor as a sensor changes, if a threshold value to determine On/Off is set at an absolute value of capacitance, such a threshold value is required to be set taking the above variations into account. Thus, if the initial value of capacitance varies among sensors, an appropriate threshold value can not be determined. For example, if the amount of change in capacitance shortly before or after the pressure was exerted is within the range of varied values of the initial capacitance among sensors, an appropriate threshold value can not be determined.

By contrast, if a sensor includes reference capacitor 400, since the distances between their respective first electrodes 12 and second electrodes 22 are substantially the same in pressure sensor 100 and reference capacitor 400, the capacitance of reference capacitor 400 and the capacitance of pressure sensor 100 change mostly in the same manner, even when the thicknesses of their respective adhesive layers are different due to the varied thicknesses among the lots of adhesive film. If the sensor includes reference capacitor 400, when the capacitance of a capacitor as a sensor changes, the threshold value to determine On/Off is set based on the capacitance of reference capacitor 400. For example, the impact from the varied thicknesses of adhesive layers is eliminated by setting a base such as “when the capacitance of a capacitor as a sensor becomes the same as or greater than the capacitance of reference capacitor 400 by a few pF to scores of pF, the sensor is turned on.” Thus, malfunctions caused by irregular manufacturing results are prevented. Also, by omitting calibration, inexpensive sensors are manufactured.

FIGS. 14A and 14B show an embodiment where a pressure sensor is formed as the sensor whose capacitance is compared with that of a reference capacitor. If a reference capacitor is formed to be adjacent to a humidity sensor of the third embodiment, the capacitance is compared between the reference capacitor and the humidity sensor. Also, a reference capacitor is formed with an adhesive layer and electrodes sandwiching the adhesive layer. In addition, a through-hole conductor may be formed in the first printed wiring board or the second printed wiring board so as to be electrically connected to the first electrode or the second electrode of the reference capacitor.

A sensor and a method for manufacturing a sensor according to the fourth embodiment show the same characteristics (1)˜(14) as in the first through the third embodiments.

### Fifth Embodiment

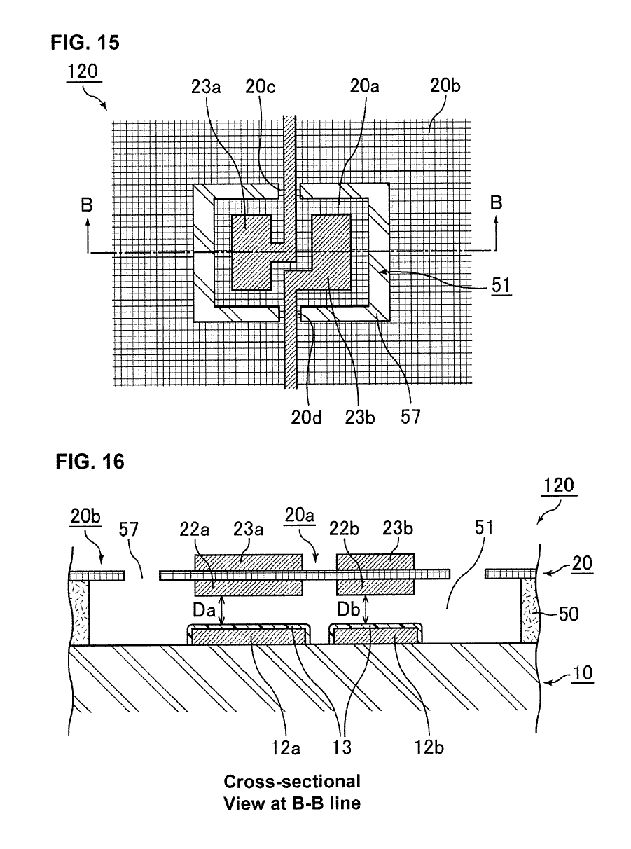

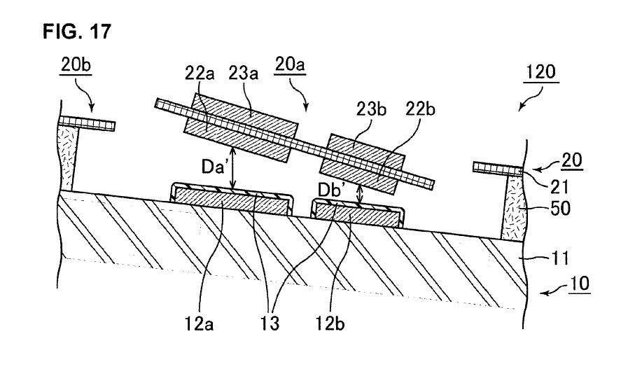

The following describes a sensor and a method for manufacturing a sensor according to the fifth embodiment of the present invention. FIG. 15 is a top view schematically showing an example of the structure of capacitors to be used as an angle sensor. Second printed wiring board (20a) and second printed wiring board (20b) shown in FIG. 15 are formed from the same substrate. FIG. 16 is a cross-sectional view of the structure of the capacitors taken at the B-B line in FIG. 15. FIG. 17 is a cross-sectional view schematically showing a state when the capacitors having the structure shown in FIG. 16 are inclined.

A sensor according to the fifth embodiment of the present invention has angle sensor 120. Second printed wiring board 20 of angle sensor 120 is separated into floated second printed wiring board (20a) positioned in the center, fixed second printed wiring board (20b) positioned outside, anchor portion (20c) and anchor portion (20d). Groove 57 exists between floated second printed wiring board (20a) and fixed second printed wiring board (20b). Groove 57 is contiguous to space 51 between second printed wiring board 20 and first printed wiring board 10. Floated second printed wiring board (20a) is connected to fixed second printed wiring board (20b) by anchor portion (20c) and anchor portion (20d). Anchor portion (20c) and anchor portion (20d) are formed like bridges connecting floated second printed wiring board (20a) and fixed second printed wiring board (20b). Anchor portion (20c) is connected to dummy electrode (23a), and anchor portion (20d) is connected to dummy electrode (23b). Dummy electrode (23a) and dummy electrode (23b) are shaped to correspond to the shapes of later-described second electrode (22a) and second electrode (22b) respectively.

As shown in FIG. 16, floated second printed wiring board (20a) floats in space 51 when seen in a cross-sectional view taken at the B-B line, and is supported only by anchor portion (20c) and anchor portion (20d). Floated second printed wiring board (20a) includes two second electrodes (second electrode (22a) and second electrode (22b)).

First printed wiring board 10 has two first electrodes (first electrode (12a) and first electrode (12b)). First electrode (12a), second electrode (22a) and space 51 form a capacitor (capacitor “a”); and first electrode (12b), second electrode (22b) and space 51 form a capacitor (capacitor “b”). Insulative film 13 is formed on the top surfaces of first electrode (12a) and first electrode (12b). As for insulative film 13, the same insulative film is used for the capacitor included in a sensor according to the first embodiment.

FIG. 16 shows a state in which angle sensor 120 is not inclined. In such a state, distance (Da) between first electrode (12a) and second electrode (22a) is the same as distance (Db) between first electrode (12b) and second electrode (22b). Therefore, the capacitance of capacitor “a” is equal to the capacitance of capacitor “b”.

FIG. 17 is a state in which angle sensor 120 is inclined. In FIG. 17, the inclination of floated second printed wiring board (20a) is greater than the inclination of angle sensor 120 (the inclination of substrate 11). Accordingly, distance (Da′) between first electrode (12a) and second electrode (22a) differs from distance (Db′) between first electrode (12b) and second electrode (22b), resulting in Da′>Db′. As a result, a difference is generated between the capacitance of capacitor “a” and the capacitance of capacitor “b”. In a sensor according to the present embodiment, when the difference between the capacitance of capacitor “a” and the capacitance of capacitor “b” exceeds a predetermined value, it is determined that the sensor is inclined. In addition, by determining whether the value of (capacitance of capacitor “a”—capacitance of capacitor “b”) is positive or negative, the direction in which the sensor is inclined is determined. Having such a structure, a sensor according to the present embodiment is used as an angle sensor.

Also, if sensor 120, which is rotated 90 degrees from sensor 120 shown in FIG. 15, is arranged in the same wiring board, the inclination in a direction X and the inclination in a direction Y are measured by the same wiring board.

In addition, a through-hole conductor electrically connected to a first electrode or a second electrode may be formed in the first printed wiring board or a second printed wiring board.

Furthermore, in examples of the structure of capacitors shown in FIGS. 16 and 17, the first electrode is separated into first electrode (12a) and first electrode (12b). However, since the first electrodes facing second electrode (22a) and second electrode (22b) work as ground, they may be a common electrode (one electrode).

In a method for manufacturing a sensor according to the present embodiment, conductive circuits and dummy conductive circuits are formed during the process for forming second printed wiring board 20 so that second electrode (22a), second electrode (22b), dummy electrode (23a), dummy electrode (23b), anchor portion (20c) and anchor portion (20d) are formed. Also, groove 57 is formed in a region between floated second printed wiring board (20a) and fixed second printed wiring board (20b) excluding anchor portion (20c) and anchor portion (20d). The rest is the same as the method for manufacturing a sensor according to the first embodiment.

A sensor and a method for manufacturing a sensor according to the fifth embodiment show the same characteristics (1), (3), (4), (6)˜(8) and (10) along with the following characteristics.

(16) In a sensor according to the present embodiment, a space exists between the first printed wiring board and the second printed wiring board, the number of second electrodes is two, the two second electrodes are each connected to a section outside the space, and the two second electrodes move independently within the space. A sensor of the present embodiment has at least two capacitors including the above two second electrodes, and works as an angle sensor by sensing the difference in the amount of change in capacitance of each capacitor when the sensor is inclined.

### Other Embodiments

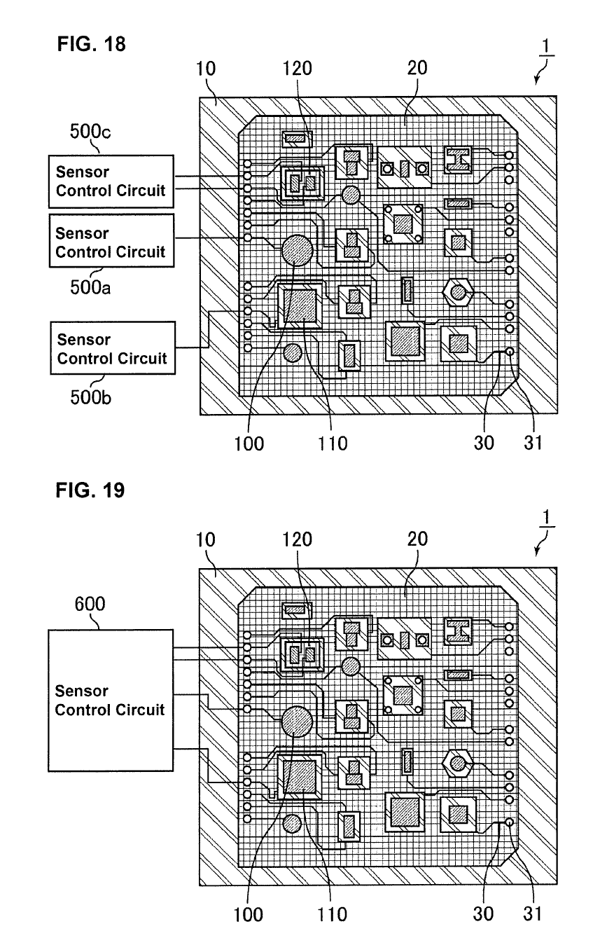

The value of capacitance of a capacitor included in a sensor according to each embodiment described so far is measured by a sensor control circuit connected to the sensor. FIG. 18 is a top view of an example schematically showing how sensor control circuits are connected to the sensor of the present invention. In FIG. 18, multiple sensor control circuits (sensor control circuit 500a, sensor control circuit 500b and sensor control circuit 500c) are connected to sensor 1. In FIG. 18, a sensor control circuit is set up for each sensor; sensor control circuit (500a) is connected to pressure sensor 100, sensor control circuit (500b) to humidity sensor 110 and sensor control circuit (500c) to angle sensor 120.

FIG. 19 is a top view of another example schematically showing how a sensor control circuit is connected to the sensor of the present invention. In FIG. 19, a sensor control circuit (sensor control circuit 600) is connected to sensor 1. In FIG. 19, the same control circuit 600 is connected to pressure sensor 100, humidity sensor 110 and angle sensor 120.

Sensor control circuit 600 has a circuit which distinguishes the amount of change in capacitance measured in each sensor and handles it accordingly, and has functions of outputting changes in characteristic values in pressure, humidity, angle and the like using one sensor control circuit.

In each embodiment described so far, capacitors with different structures are separately described. However, using a method for manufacturing a sensor of the present invention, capacitors with different structures are formed on the same wiring board through the same procedure. In particular, during the process for forming wiring and electrodes in a first printed wiring board or a second printed wiring board, it is only required to form a pattern suitable for the structure of each capacitor. Also, it is sufficient to conduct a step for forming an insulation layer or space filler in the space only for the portion that requires such a structure.

In each embodiment, an example is described in which the first printed wiring board is a rigid wiring board and the second printed wiring board is a flexible wiring board. However, the first printed wiring board and the second printed wiring board may be both rigid wiring boards or both flexible wiring boards.

When the first printed wiring board and the second printed wiring board are both rigid wiring boards, they are used for a purpose that does not require elasticity, for example, as a humidity sensor. When the first printed wiring board and the second printed wiring board are both flexible wiring boards, they are used, for example, as a pressure sensor using the elasticity of the wiring boards.

A sensor according to an embodiment of the present invention includes the following: a first printed wiring board; a first electrode made of metal film and formed on the first printed wiring board; a second printed wiring board positioned to face the first printed wiring board; a second electrode made of metal film and formed on the second printed wiring board to face the first electrode; and a dielectric body including an insulation layer or a space which exists at least in a partial portion between the first electrode and the second electrode. In such a sensor, a capacitor is formed with the dielectric body and with the first electrode and the second electrode sandwiching the dielectric body.

In the sensor described above, the first printed wiring board and the second printed wiring board are positioned to face each other, and electrodes to form a capacitor are positioned to face their respective printed wiring boards. Then, a dielectric body is positioned between the two electrodes. In such a structure, the capacitance of the capacitor is determined by the distance between the first electrode and the second electrode and by the dielectric constant of the dielectric body. Since the distance between the first electrode and the second electrode substantially corresponds to the distance between the first printed wiring board and the second printed wiring board, a sensor with predetermined capacitance is obtained by setting the distance between the first printed wiring board and the second printed wiring board at a predetermined value. As a result, a simplified and inexpensive sensor is obtained without requiring a semiconductor manufacturing process or MEMS technology.

In the sensor, at least either the first printed wiring board or the second printed wiring board may be a flexible printed wiring board. Since a flexible printed wiring board warps when pressure is exerted, the position of the electrode in the flexible printed wiring board is easily changed in response to the pressure, leading to a change in the distance between the electrodes. The capacitance changes in response to such a change. As a result, a simplified and inexpensive sensor is obtained without requiring a semiconductor manufacturing process or MEMS technology.

In the sensor, a dummy electrode corresponding to the pattern of the first electrode or the second electrode may be formed on a surface opposite the surface of the flexible printed wiring board on which the first electrode or the second electrode is formed. If patterns having the same shape are formed on both surfaces of a flexible printed wiring board, the flexible printed wiring board is prevented from warping.

In the sensor, at least either the first printed wiring board or the second printed wiring board may be elastic. Since an elastic printed wiring board warps when pressure is exerted, the position of the electrode arranged on the elastic printed wiring board is easily changed in response to the pressure. As a result, the distance between the electrodes is changed, leading to a change in capacitance. Accordingly, a simplified and inexpensive sensor is obtained without requiring a semiconductor manufacturing process or MEMS technology. When the pressure is released, due to its elasticity the printed wiring board is returned to its original position. Thus, the sensor of the embodiment is repeatedly used as a pressure sensor.

The sensor may sense a change in the capacitance of the capacitor.

In the sensor, the capacitance may change in response to a change in the distance between the first electrode and the second electrode.

In the sensor, the capacitance may change in response to a change in the dielectric constant of the dielectric body.

In the sensor, the dielectric constant may change in response to a change in humidity.

The sensor may work as a pressure sensor.

When the distance is changed between the first electrode and the second electrode, or when the dielectric constant of the dielectric body is changed, the capacitance of the capacitor changes accordingly. Then, by sensing a change in the capacitance of the capacitor, the sensor of the embodiment is used for purposes such as that of a pressure sensor, acceleration sensor, humidity sensor or the like.

The sensor may include at least two of the above capacitors and works as an angle sensor by sensing a difference in the amount of change in the capacitance of each capacitor caused when the sensor is inclined.

In the sensor, a space may exist between the first printed wiring board and the second printed wiring board, the number of the second electrodes is two or more, the two or more second electrodes are each connected to the outside of the space, and the two or more second electrodes move independently within the space.

In the sensor, the second printed wiring board may be a flexible printed wiring board.

In the sensor according to the embodiment, the capacitance of each capacitor may change when the sensor is inclined. The amount of change is different in each capacitor. Thus, the sensor of the embodiment is used as an angle sensor by sensing a difference in the amount of change in the capacitance of each capacitor. In addition, according to the structure of the sensor, such a sensor may be used preferably as an angle sensor.

The sensor may further include at least one reference capacitor having a substantially constant capacitance, and senses the difference in capacitance between the reference capacitor and the above capacitor.

When a reference capacitor having a substantially constant capacitance is included, a threshold value to determine On/Off responding to a change in the capacitance of the capacitor as a sensor is set as the amount of change in the difference with the capacitance of the reference capacitor. When the threshold value is determined not according to an absolute value in capacitance but according to the above method, malfunctions caused by irregular manufacturing results are prevented. Also, by omitting calibration, inexpensive sensors are manufactured.

The sensor may further include insulative film formed on the upper surface of the first electrode or on the upper surface of the second electrode.

When insulative film is formed on an electrode, short circuiting is prevented from occurring between electrodes even when the distance between the first electrode and the second electrode decreases due to pressure exerted on the sensor. Such insulative film also works as a dielectric body between the electrodes. Also, the insulative film works as antioxidation film between the electrodes.

The sensor may further include an adhesive layer between the first printed wiring board and the second printed wiring board so as to adhere the first printed wiring board and the second printed wiring board.

When the first printed wiring board and the second printed wiring board are adhered, the distance between the first printed wiring board and the second printed wiring board is set as the thickness of the adhesive layer.

In the sensor, the adhesive layer may not cover at all the upper surface of the first electrode.

When the adhesive layer does not cover at all the upper surface of the first electrode, a space exists on the first electrode, and such a space becomes a dielectric body. According to such a structure, since the thickness of the space as a dielectric body corresponds to the thickness of the adhesive layer, the thickness of the dielectric body is controlled by adjusting the thickness of the adhesive layer. Therefore, a capacitor with a predetermined capacitance is obtained.

In the sensor, a through-hole conductor to be electrically connected to the first electrode may be formed in the first printed wiring board. In the sensor, a through-hole conductor to be electrically connected to the second electrode may be formed in the second printed wiring board.

When a through-hole conductor to be electrically connected to an electrode of a capacitor is formed, the capacitor and external wiring are electrically connected by the through-hole conductor. Then, the electric capacity of the capacitor is easily measured.

In the sensor, at least two types of sensors selected from among a group of pressure, humidity and angle sensors may be formed through the same process on the same wiring board.

According to such a sensor, at least two types of characteristic values selected from among a group of pressure, humidity and angle sensors are measured by a single sensor control circuit.

In the sensor, a penetrating hole connected to the space may be formed either in the first printed wiring board or in the second printed wiring board.

According to such a structure, when the air in the space is expanded by the heat during a reflow, such expanded air exits through the penetrating hole. Thus, an electrode is prevented from being removed from a printed wiring board.

A keyboard may include the sensor described above.

Since the sensor includes a capacitor suitable for working as a sensor by sensing a change in capacitance, the sensor is used preferably as a component of a keyboard.

A method for manufacturing a sensor according to an embodiment of the present invention includes the following: preparing a first substrate; manufacturing a first printed wiring board by forming a first electrode made of metal film on the first substrate; preparing a second substrate; manufacturing a second printed wiring board by forming a second electrode made of metal film on the second substrate; forming insulative film on a surface of the first electrode; preparing adhesive film having an opening at a predetermined location; laminating the adhesive film on the first printed wiring board by aligning the opening with the position of the first electrode; and laminating and pressing the second printed wiring board on the adhesive film by aligning the second electrode with the position of the opening.

The sensor described above may be manufactured preferably according to the above method.

Obviously, numerous modifications and variations of the present invention are possible in light of the above teachings. It is therefore to be understood that within the scope of the appended claims, the invention may be practiced otherwise than as specifically described herein.

What is claimed is:

1. A sensor, comprising:
a first printed wiring board having a first electrode comprising a metal film;
a second printed wiring board facing the first printed wiring board and having a second electrode comprising a metal film, the second electrode being positioned on the second printed wiring board such that the second electrode faces the first electrode of the first printed wiring board; and
a dielectric body spacing the first electrode and the second electrode apart such that the first electrode, the second electrode and the dielectric body form a capacitor.

2. The sensor according to claim 1, wherein at least one of the first printed wiring board and the second printed wiring board is a flexible printed wiring board.

3. The sensor according to claim 2, further comprising a dummy electrode formed on a surface of the flexible printed wiring board, wherein the dummy electrode is positioned on an opposite side of the first electrode or the second electrode formed on the flexible printed wiring board and is corresponding to a pattern of the first electrode or the second electrode.

4. The sensor according to claim 1, wherein at least one of the first printed wiring board and the second printed wiring board is elastic.

5. The sensor according to claim 1, wherein the dielectric body between the fist electrode and the second electrode is a space, and the capacitor is configured to change capacitance in accordance with a change in a distance in the space between the first electrode and the second electrode.

6. The sensor according to claim 1, wherein at least one of the first electrode and the second electrode comprises an electroless plating layer and an electrolytic plating layer.

7. The sensor according to claim 1, wherein the dielectric body between the first electrode and the second electrode is an insulative layer, and the capacitor is configured to change capacitance in response to a change in dielectric constant of the dielectric body.

8. The sensor according to claim 7, wherein the capacitor is configured to change capacitance in response to a change in humidity.

9. The sensor according to claim 1, wherein the dielectric body between the fist electrode and the second electrode is a space, and the capacitor is configured to change capacitance in accordance with a change in pressure in the space.

10. The sensor according to claim 1, wherein the dielectric body between the fist electrode and the second electrode is a space, the capacitor is formed in a plurality, and the plurality of capacitors is configured to detect a change in angle based on a difference in an amount of change in capacitance of each of the capacitors.

11. The sensor according to claim 10, wherein the second electrode is formed in a plurality, and the plurality of second electrodes is configured such that the second electrodes independently move within the space.

12. The sensor according to claim 11, wherein the second printed wiring board is a flexible printed wiring board.

13. The sensor according to claim 1, further comprising at least one reference capacitor having substantially a constant capacitance, wherein the sensor is configured to sense a difference in capacitance between the reference capacitor and the capacitor.

14. The sensor according to claim 1, further comprising an insulative film formed on a surface of one of the first electrode and the second electrode.

15. The sensor according to claim 1, further comprising an adhesive layer positioned between the first printed wiring board and the second printed wiring board, wherein the first printed wiring board and the second printed wiring board are adhered via the adhesive layer.

16. The sensor according to claim 1, wherein the dielectric body between the first electrode and the second electrode is a space.

17. The sensor according to claim 1, wherein the first printed wiring board has a substrate and has a through-hole conductor formed through the substrate and electrically connected to the first electrode.

18. The sensor according to claim 1, wherein the second printed wiring board has a substrate and a through-hole conductor formed through the substrate and electrically connected to the second electrode.

19. The sensor according to claim 1, wherein the dielectric body between the first electrode and the second electrode is a space, and one of the first printed wiring board and the second printed wiring board has a penetrating hole connected to the space.

20. A keyboard comprising the sensor according to claim 1.

21. A method for manufacturing a sensor, comprising:
forming a first electrode comprising a metal film on a first printed wiring board;
forming a second electrode comprising a metal film on a second printed wiring board;
laminating an adhesive film having an opening portion on the first printed wiring board such that the opening portion is aligned to expose the first electrode; and
laminating the second printed wiring board on the adhesive film such that the second electrode faces the first electrode in the opening portion of the adhesive layer and the first electrode and the second electrode are spaced apart by a dielectric body and form a capacitor.

22. The method for manufacturing a sensor according to claim 21, further comprising forming an insulative film on a surface of the first electrode.
